(19) United States
(12) Patent Application Publication
(10) Pub. No.: US 2013/0223028 A1
(43) Pub. Date: Aug. 29, 2013

(54) HYBRID HOUSING FOR IMPLANTABLE MEDICAL DEVICE

(71) Applicants: Lawrence Arne, Palo Alto, CA (US); Marc Jensen, Los Gatos, CA (US); Todd Thompson, San Jose, CA (US)

(72) Inventors: Lawrence Arne, Palo Alto, CA (US); Marc Jensen, Los Gatos, CA (US); Todd Thompson, San Jose, CA (US)

(73) Assignee: PROTEUS DIGITAL HEALTH, INC., Redwood City, CA (US)

(21) Appl. No.: 13/812,849

(22) PCT Filed: Jul. 25, 2011
(86) PCT No.: PCT/US2011/045227

§ 371 Date: Feb. 19, 2013

Related U.S. Application Data
(60) Provisional application No. 61/368,987, filed on Jul. 29, 2010.

(51) Int. Cl. H05K 5/06; H05K 13/00

(52) U.S. Cl. CPC H05K 5/069; H05K 13/00
USPC 361/757; 361/752; 29/592.1

(57) ABSTRACT

Apparatuses and methods for hybrid housings as well as hybrid housing based implantable medical devices are provided. A hybrid housing comprises a ceramic substrate, a bonding structure formed on the periphery of the ceramic substrate, and a biocompatible metal cap coupled to the ceramic substrate using the bonding structure to form a hermetically sealed enclosure. One or more electronic elements may be formed within the hermetically sealed enclosure, and the electronic elements may be stably associated with the ceramic substrate.

### CROSS-REFERENCE TO RELATED APPLICATIONS

Pursuant to 35 U.S.C. §119, this application claims priority to the filing date of U.S. Provisional Patent Application Ser. No. 61/368,987, filed Jul. 29, 2010 and entitled “Hybrid Housing for Implantable Medical Device,” which application is hereby incorporated by reference in its entirety.

### INTRODUCTION

Implantable medical devices are inserted into a living body to perform a number of functions, such as delivery of drug, sensing or stimulating a target area in the living body, etc. Since the implantable medical devices come in contact with living tissues and/or fluid surrounding them, the devices need to be biocompatible. For example, cobalt, nickel, steel, iron nickel alloy, etc. may not be suitable as a housing material for the implantable medical devices since such metals or metal alloys may slowly dissolve when they are exposed to a saline solution or other bodily fluids present in the living body. Accordingly, biocompatible metals or metal alloys, such as titanium (Ti), platinum (Pt), niobium (Nb), and alloys of those materials, are used as a housing material for the implantable medical devices.

Further, the functions performed by the implantable medical devices often require an effective communication between the implantable medical devices and internal or external control devices associated with the implantable medical devices residing within the living body. For example, power or energy may need to be delivered to recharge the implantable medical devices since it may be difficult to get to the implantable medical devices nonintrusively. Further, signals may need to be communicated between the internal or external control devices and the implantable medical devices to perform such functions as the delivery of drug or sensing or stimulating the target area in the living body.

However, the biocompatible metals or metal alloys may have a trouble communicating a high frequency signal via them when they are used as a housing material since their permittivity for high frequency signal is known to be low. For example, titanium (Ti) may not be a good housing material in high frequency signal communication (e.g., above 150 KHz) since the cutoff frequency for titanium housing is around 150 KHz.

Furthermore, it may be difficult to reduce the size of the implantable medical devices based on a biocompatible metal or metal alloy housing since electronic, electrical and/or mechanical elements (e.g., such as a circuit board, passive components, reservoir(s) for drug, antenna, rechargeable battery, etc.) that are implemented inside the housing may need to be built on a platform which is separate from the metal or metal alloy housing.

### BRIEF DESCRIPTION OF THE FIGURES

FIG. 1 illustrates a first exemplary implantable medical device.

FIG. 2 illustrates an exemplary hybrid housing for an implantable medical device.

FIG. 3 illustrates a cross-sectional view of another exemplary hybrid housing for an implantable medical device.

FIG. 4 illustrates a second exemplary implantable medical device with a number of electronic elements.

FIG. 5 illustrates a third exemplary implantable medical device.

FIG. 6 illustrates a fourth exemplary implantable medical device.

FIG. 7 illustrates an exemplary method for forming an implantable medical device based on a hybrid housing.

### DETAILED DESCRIPTION

Reference will now be made in detail to the aspects of the invention, examples of which are illustrated in the accompanying drawings. While the invention will be described in conjunction with the aspects, it will be understood that they are not intended to limit the invention to these aspects. On the contrary, the disclosure is intended to cover alternatives, modifications and equivalents, which may be included within the spirit and scope of the invention. Furthermore, in the detailed description, numerous specific details are set forth in order to provide a thorough understanding of the present disclosure. However, it will be obvious to one of ordinary skill in the art that the present disclosure may be practiced without these specific details. In other instances, well known methods, procedures, components, and circuits have not been described in detail as not to unnecessarily obscure aspects of the present invention.

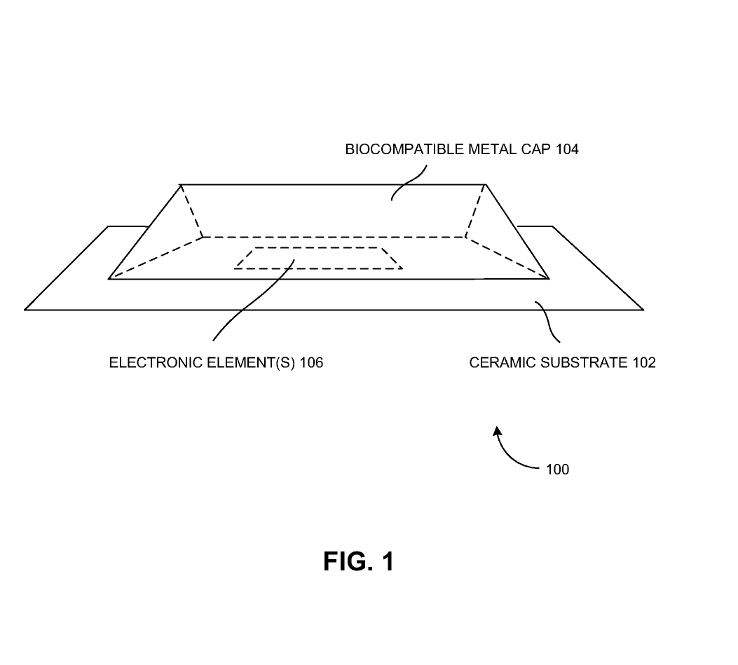

FIG. 1 illustrates a first exemplary implantable medical device 100. In FIG. 1, the implantable medical device 100 comprises a hybrid housing based on a ceramic substrate 102 and a biocompatible metal cap 104 as well as one or more electronic elements 106. Alternatively, a biocompatible ceramic cap may be used instead of the biocompatible metal cap 104. In one example implementation, the electronic elements 106 may be formed on to or into the ceramic substrate 102. Alternatively, the electronic elements 106 may be directly implemented on to or into the ceramic substrate 102. In yet another example, the electronic elements 106 may be formed on a circuit board which is coupled to the ceramic substrate 102 using a bonding material (e.g., bonding ball, bonding wire, etc.) The biocompatible metal cap 104 is coupled to the ceramic substrate 102 to form a hermetically sealed enclosure which is used to protect the electronic elements 106 from bodily fluid.

In one aspect, the ceramic substrate 102 is planar as illustrated in FIG. 1. In an example implementation, a hybrid housing based on a biocompatible cap (e.g., a cylinder, sphere, etc.) coupled to a planar ceramic substrate may be easy and cost effective to manufacture. In another aspect, the ceramic substrate 102 is made of alumina, sapphire, or zirconia. In one example implementation, the biocompatible metal cap 104 is made of titanium (Ti), platinum (Pt), niobium (Nb), or an alloy of the titanium, the platinum, or the niobium.

Further, the ceramic substrate 102 may be a multi-layered substrate, such as a high temperature cofired ceramic (HTCC) alumina substrate or a low temperature cofired ceramic (LTCC) alumina substrate. It is appreciated that the HTCC alumina substrate is based on a multi-layer packaging technology, used in military electronics, MEMS, microprocessor and RF applications. The HTCC packages may comprise multi-layers of alumina oxide with tungsten and molymanganese metallization, where the ceramic is fired at around 1600 degrees Celsius, and make a highly reliable, stress resistant, and high performance packaging choice thanks to their mechanical rigidity and hermeticity.

The LTCC technology may be defined as a way to produce multilayer circuits with the help of single tapes, which are to be used to apply conductive, dielectric and/or resistive pastes on. These single sheets have to be laminated together and fired in one step all. This saves time, money and reduces circuit dimensions. Another advantage of the LTCC may be that every single layer can be inspected, and in the case of inaccuracy or damage, replaced before firing; this prevents the need of manufacturing a whole new circuit. Further, because of the low firing temperature of about 850° C. used in the LTCC technology, it may be possible to use the low resistive materials silver and gold instead of molybdenum and tungsten, which have to be used in conjunction with the HTCCs. Thus, the LTCC technology may be also advantageous as it doesn't utilize tungsten, which has biocompatibility issues, when a device based on tungsten comes in contact with tissues due to a mechanical failure or some other reason.

Further, the ceramic substrate 102, which may be based on the multi-layered HTCC or LTCC technology, may comprise one or more diffusion barriers, where each of the diffusion barriers may be a thin layer, usually micrometers thick, of metal usually placed between two other metals. It is done to act as a barrier to protect either one of the metals from corrupting the other. In one example implementation, the diffusion barriers may be implemented using metals, such as platinum (Pt), platinum iridium (Pt—Ir), titanium (Ti), gold (Au), tungsten (W), copper (Cu), aluminum (Al), tantalum (Ta), etc. or using conductive links. The materials for the conductive links may be deposited by a thick film printing, plating, evaporation, or Arc-PVD. The layers may be further modified by etching, masking, laser cutting, or machining.

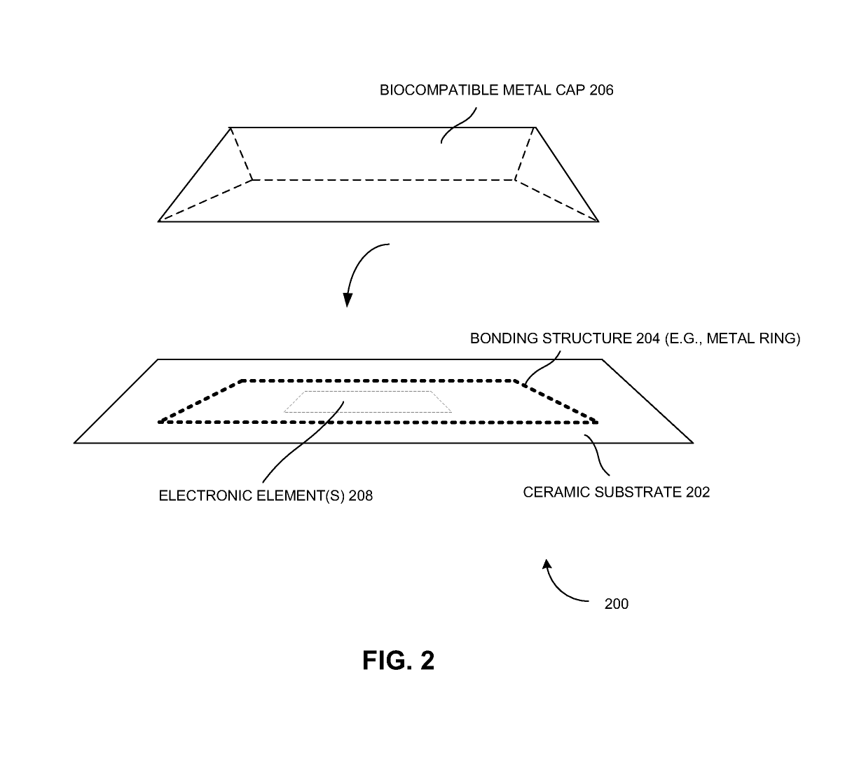

FIG. 2 illustrates an exemplary hybrid housing 200 for an implantable medical device. The hybrid housing 200 comprises a ceramic substrate 202, a bonding structure 204 formed on the periphery of the ceramic substrate 202, and a biocompatible metal cap 206 coupled (e.g., laser welded, brazed, etc.) to the ceramic substrate 202 using the bonding structure 204 to form a hermetically sealed enclosure, where the bonding structure 204 is brazed to the ceramic substrate 202, and the biocompatible metal cap 206 is laser welded to the bonding structure 204. Alternatively, the bonding structure 204 may be eliminated, and an Arc-PVD deposition may be employed to seal the joint between the biocompatible metal cap 206 and the ceramic substrate 202. It is appreciated that the Arc-PVD technique is a physical vapor deposition technique in which an electric arc is used to vaporize material from a cathode target. The vaporized material then condenses on a substrate, forming a thin film. The technique can be used to deposit metallic, ceramic, or composite films, or to seal a joint connecting two or more pieces.

One or more electronic elements 208 may be formed within the hermetically sealed enclosure, and the electronic elements 208 may be stably associated (e.g., physically fixed to, communicatively and/or electrically coupled to, etc.) with the ceramic substrate 202. In one aspect, the bonding structure 204 is a metal ring formed on the periphery of the ceramic substrate 202, and the biocompatible metal cap 206 is welded to the metal ring formed on the periphery of the ceramic substrate 202.

In another aspect, the ceramic substrate 202 comprises electrical/electronic components with electrical functionality as well as structures with barrier function. The ceramic substrate 202 may be also equipped with pads used to mount the electrical/electronic components onto the ceramic substrate 202, bonding pads wherein the components are mounted using a bonding technique (e.g., wire-bonding, ball-bonding, etc.), traces forming electrical interconnects, traces forming resistors, capacitors, inductors, etc., antennas for wireless communication, vias where the electrical interconnect spans multiple layers in the ceramic substrate 202, and electrodes or contact points for making measurements inside the body and/or stimulating living tissues or organs. The electrical functions may be implemented by multiple deposition/etch layers to further enhance the functions, such as using titanium as an adhesive layer between the multiple deposition/etch layers. Alternatively, metallic features may be fabricated by stamping, laser cutting, electroforming, and/or laminated into or brazed on to the ceramic substrate 202.

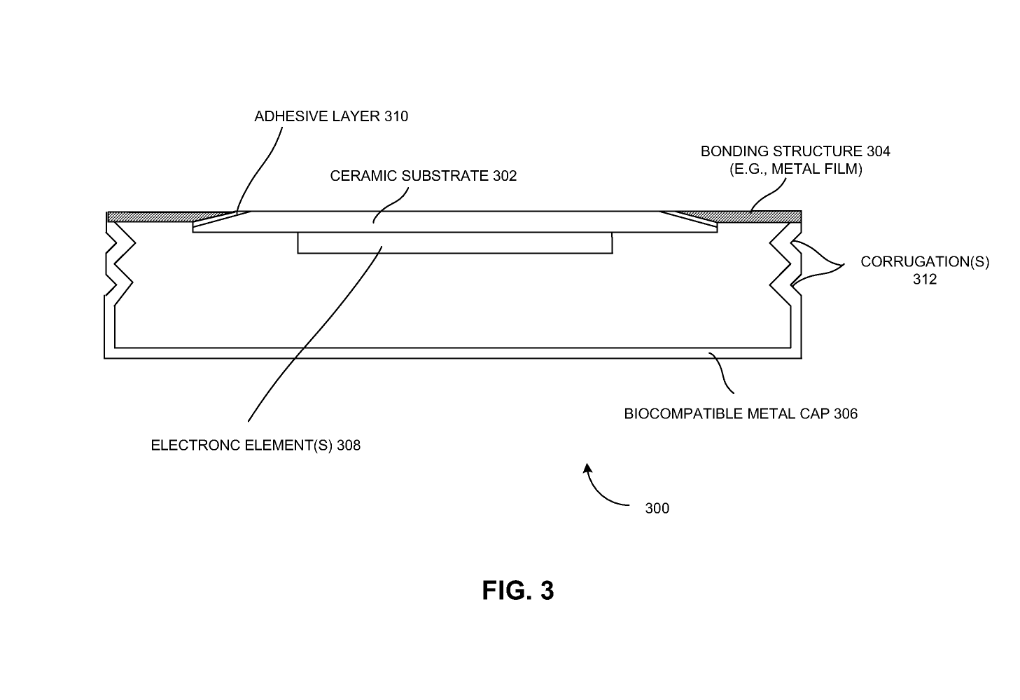

FIG. 3 illustrates a cross-sectional view of another exemplary hybrid housing 300 for an implantable medical device. The hybrid housing 300 comprises a ceramic substrate 302, a bonding structure 304 formed on the periphery of the ceramic substrate 302, and a biocompatible metal cap 306 coupled to the ceramic substrate 302 using the bonding structure 304 to form a hermetically sealed enclosure. One or more electronic elements 308 may be formed within the hermetically sealed enclosure, and the electronic elements 308 may be stably associated with the ceramic substrate 302. In one aspect, the bonding structure 304 is a metal film formed on the periphery of the ceramic substrate 302, and the biocompatible metal cap 306 is welded to the metal ring formed on the periphery of the ceramic substrate 302.

The metal film may be formed on the periphery of the ceramic substrate 302 using the Arc-PVD technique, and then the metal film may be polished or refined. Additionally, an adhesive layer 310 may be formed between the ceramic substrate 302 and the metal film. Once the metal film is formed, the biocompatible metal cap 306 may be positioned on the bonding structure 304, and the part adjoining the biocompatible metal cap 306 and the bonding structure 304 (e.g., the metal film) is welded. In one aspect, the biocompatible metal cap 306 may be formed with one or more corrugations to reduce sidewall modulus, thereby reducing any coefficient thermal expansion (CTE) stresses present on the ceramic substrate 302. Further, silicon carbide (SiC) or film may be applied on the ceramic substrate 302 or a joint connecting the ceramic substrate 302 and the biocompatible metal cap 306 for more robustness.

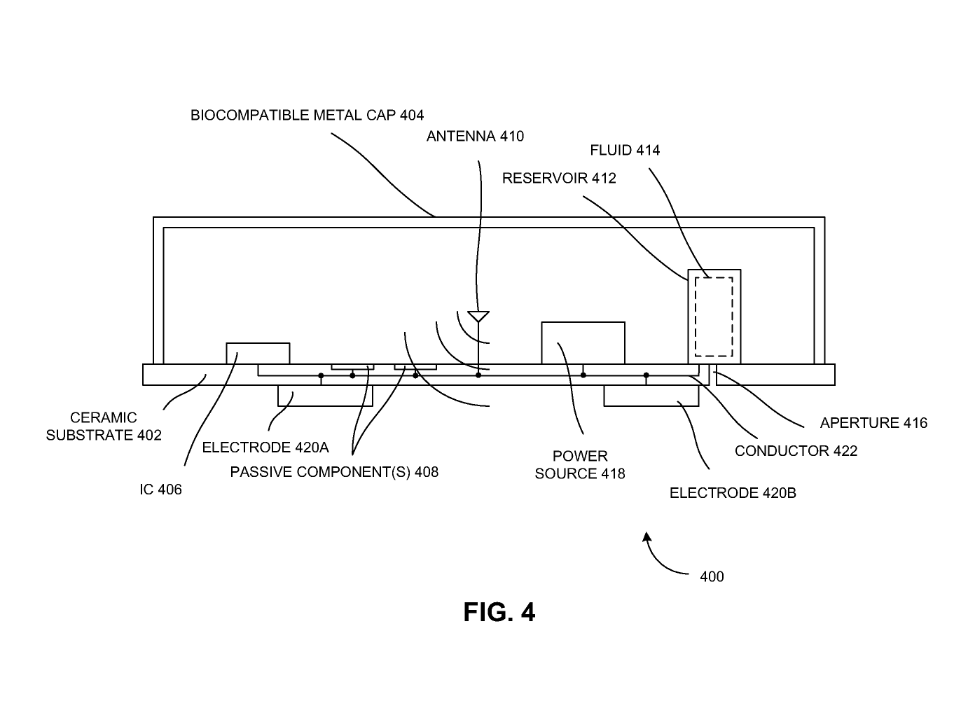

FIG. 4 illustrates a second exemplary implantable medical device 400 with a number of electronic elements. In FIG. 4, the implantable medical device 400 comprises a ceramic substrate 402, a biocompatible metal cap 404, and one or more electronic elements stably associated with the ceramic substrate 402. In one aspect, the electronic elements may include an integrated circuit (IC) 406, passive components 408 (e.g., resistors, capacitors, inductors, diodes, etc.), an antenna 410, a reservoir 412 containing fluid 414 (e.g., medication, hormone, etc.), a power source 418 (e.g., rechargeable battery), and one or more electrodes (e.g., an electrode 420A and an electrode 420B). In one exemplary implementation, the electrode 420A may be a sensor, whereas the electrode 420B may be a stimulator. That is, the electrode 420A may be used to sense heart rate, EEG, EMG, etc., and the electrode 420B may be used for cardiac or spinal code pacing. The electrode 420A may be also used to sense impulse modulation (IM) signal to or from the implantable medical device 400. The electrical elements may be connected using a conductor 422 formed in the ceramic substrate 402.

In FIG. 4, the fluid 414 may be released from the reservoir 412 via an aperture 416. Further, a high frequency signal (e.g., above 150 KHz) blocked by the biocompatible metal cap 404 is communicated to or from the hermetically sealed enclosure via the ceramic substrate 402. That is, the biocompatible metal cap 404, for example, a titanium cap, is also an excellent shield blocking radio frequency (RF) above 150 KHz. Such characteristic of the biocompatible metal cap 404 may be undesirable where new medical implants use medical implant communication service (MICS) band RF, which broadcasts around 402 MHz. The ceramic substrate 402 may also be used to pass through magnetic flux used to charge the power source 418.

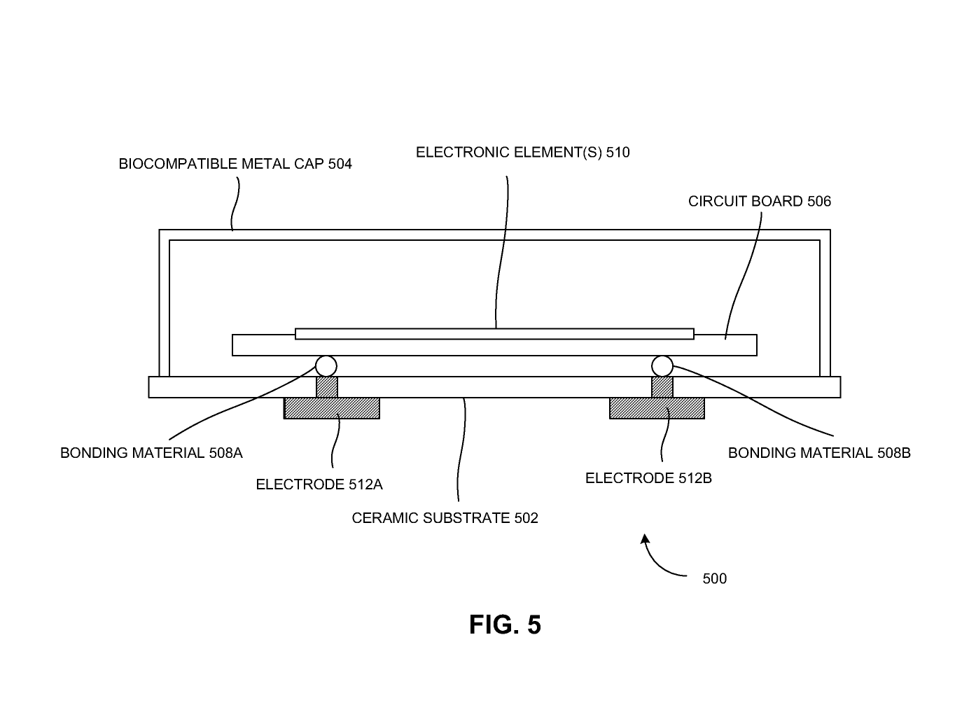

FIG. 5 illustrates a third exemplary implantable medical device 500. In FIG. 5, the implantable medical device 500 comprises a hybrid housing based on a ceramic substrate 502 and a biocompatible metal cap 504. Further, the implantable medical device 500 comprises a circuit board 506 coupled to the ceramic substrate 502 via a bonding material 508A-B (e.g., bonding ball, bonding wire, solder, etc.). The circuit board 506 may be made of various materials, such as FR4, polyamide, etc. One or more electronic elements 510 are implemented or formed on to and/or into the circuit board 506. Further, one or more electrodes (e.g., an electrode 512A and an electrode 512B) are formed on to the ceramic substrate 502, and the electrodes may be coupled to the electronic elements via the bonding materials 508A-B.

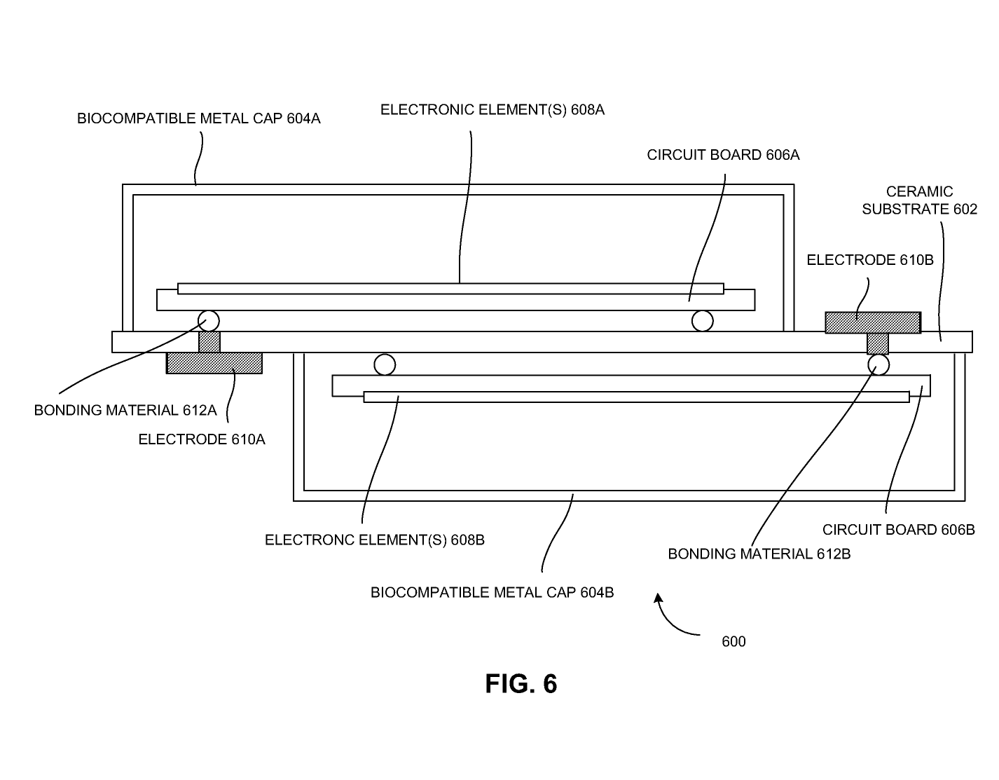

FIG. 6 illustrates a fourth exemplary implantable medical device 600. In FIG. 6, the implantable medical device 600 comprises a first hybrid housing based on a ceramic substrate 602 and a biocompatible metal cap 604A. The implantable medical device 600 further comprises a second hybrid housing based on the ceramic substrate 602 and a biocompatible metal cap 604B. The first hybrid housing encloses a circuit board 606A comprising one or more electronic elements 608A which couple with an electrode 610A via a bonding material 612A. The second hybrid housing encloses a circuit board 606B comprising one or more electronic elements 608B which couple with an electrode 610B via a bonding material 612B. As illustrated in FIG. 6, the second hybrid housing may be formed on the opposite side of the first hybrid housing with respect to the ceramic substrate 602 to form two hermetically sealed enclosures.

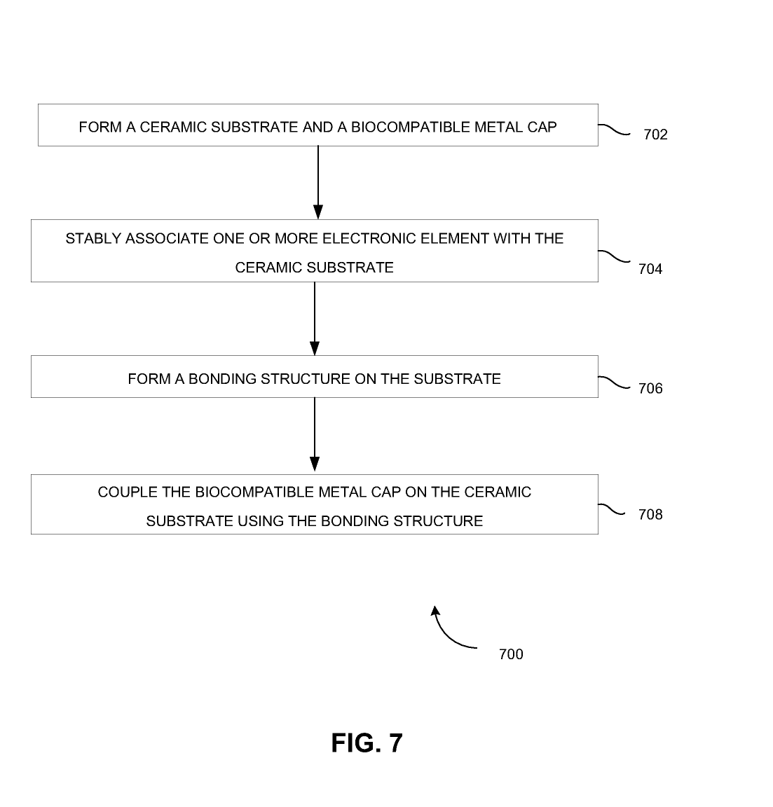

FIG. 7 illustrates an exemplary method 700 for forming an implantable medical device based on a hybrid housing. In step 702, a ceramic substrate and a biocompatible metal cap are formed. The biocompatible cap may be fabricated using one or more techniques which include deep drawing, stamping, welding, electroforming, cathodic arc deposition, etc. Once the biocompatible cap is fabricated, it may be laser welded to the ceramic substrate. In one aspect, one or more diffusion barriers may be formed into the ceramic substrate. In step 704, one or more electronic elements are stably associated with the ceramic substrate. In step 706, a bonding structure is formed on to the substrate. In one aspect, a metal film may be formed on a periphery of the ceramic substrate as the bonding structure using the cathodic arc deposition technique. In another aspect, a metal ring may be formed on a periphery of the ceramic substrate as the bonding structure. In step 708, the biocompatible metal cap is coupled and laser welded to the ceramic substrate using the bonding structure to form a hermetically sealed enclosure.

It is to be understood that this invention is not limited to particular aspects described, as such may vary. It is also to be understood that the terminology used herein is for the purpose of describing particular aspects only, and is not intended to be limiting, since the scope of the present invention will be limited only by the appended claims.

Where a range of values is provided, it is understood that each intervening value, to the tenth of the unit of the lower limit unless the context clearly dictates otherwise, between the upper and lower limit of that range and any other stated or intervening value in that stated range, is encompassed within the invention. The upper and lower limits of these smaller ranges may independently be included in the smaller ranges and are also encompassed within the invention, subject to any specifically excluded limit in the stated range. Where the stated range includes one or both of the limits, ranges excluding either or both of those included limits are also included in the invention.

Unless defined otherwise, all technical and scientific terms used herein have the same meaning as commonly understood by one of ordinary skill in the art to which this invention belongs. Although any methods and materials similar or equivalent to those described herein can also be used in the practice or testing of the present invention, representative illustrative methods and materials are now described.

All publications and patents cited in this specification are herein incorporated by reference as if each individual publication or patent were specifically and individually indicated to be incorporated by reference and are incorporated herein by reference to disclose and describe the methods and/or materials in connection with which the publications are cited. The citation of any publication is for its disclosure prior to the filing date and should not be construed as an admission that the present invention is not entitled to antedate such publication by virtue of prior invention. Further, the dates of publication provided may be different from the actual publication dates which may need to be independently confirmed.

It is noted that, as used herein and in the appended claims, the singular forms “a”, “an”, and “the” include plural referents unless the context clearly dictates otherwise. It is further noted that the claims may be drafted to exclude any optional element. As such, this statement is intended to serve as antecedent basis for use of such exclusive terminology as “solely,” “only” and the like in connection with the recitation of claim elements, or use of a “negative” limitation.

As will be apparent to those of skill in the art upon reading this disclosure, each of the individual aspects described and illustrated herein has discrete components and features which may be readily separated from or combined with the features of any of the other several aspects without departing from the scope or spirit of the present invention. Any recited method can be carried out in the order of events recited or in any other order which is logically possible.

Although the foregoing invention has been described in some detail by way of illustration and example for purposes of clarity of understanding, it is readily apparent to those of ordinary skill in the art in light of the teachings of this invention that certain changes and modifications may be made thereto without departing from the spirit or scope of the appended claims.

Accordingly, the preceding merely illustrates the principles of the invention. It will be appreciated that those skilled in the art will be able to devise various arrangements which, although not explicitly described or shown herein, embody the principles of the invention and are included within its spirit and scope. Furthermore, all examples and conditional language recited herein are principally intended to aid the reader in understanding the principles of the invention and the concepts contributed by the inventors to furthering the art, and are to be construed as being without limitation to such specifically recited examples and conditions. Moreover, all statements herein reciting principles, aspects, and aspects of the invention as well as specific examples thereof, are intended to encompass both structural and functional equivalents thereof. Additionally, it is intended that such equivalents include both currently known equivalents and equivalents developed in the future, i.e., any elements developed that perform the same function, regardless of structure. The scope of the present invention, therefore, is not intended to be limited to the exemplary aspects shown and described herein. Rather, the scope and spirit of present invention is embodied by the appended claims.

What is claimed is:

1. An implantable medical device, comprising:
a ceramic substrate;
at least one electronic element stably associated with the ceramic substrate; and
a biocompatible metal cap coupled to the ceramic substrate to form a hermetically sealed enclosure, wherein the at least one electronic element is formed within the hermetically sealed enclosure.

2. The device of claim 1, wherein the ceramic substrate is planar.

3. The device of claim 1, wherein the ceramic substrate is made of alumina, sapphire, or zirconia.

4. The device of claim 1, wherein the biocompatible metal cap is made of titanium, platinum, niobium, or an alloy of the titanium, the platinum, or the niobium.

5. The device of claim 1, wherein the biocompatible metal cap comprises a plurality of corrugations.

6. The device of claim 1, wherein the at least one electronic element is an integrated chip (IC), a passive component, an antenna, a reservoir, a power source, or an electrode.

7. The device of claim 1, wherein the at least one electronic element is formed on the ceramic substrate.

8. The device of claim 6, further comprising a circuit board coupled to the ceramic substrate based on a bonding material, wherein the at least one electronic element is formed on the circuit board.

9. The device of claim 1, further comprising a second biocompatible metal cap coupled to the ceramic substrate, wherein the second biocompatible metal cap is formed on the opposite side of the biocompatible metal cap with respect to the ceramic substrate to form a second hermetically sealed enclosure.

10. The device of claim 9, further comprising a second group of electrical components stably associated with the ceramic substrate, wherein the second group of electronic elements is formed within the second hermetically sealed enclosure.

11. The device of claim 1, wherein a high frequency signal blocked by the biocompatible metal cap is communicated to or from the hermetically sealed enclosure via the ceramic substrate.

12. The device of claim 1, wherein the ceramic substrate is a high temperature cofired ceramic (HTCC) alumina substrate or a low temperature cofired ceramic (LTCC) alumina substrate.

13. The device of claim 12, wherein the ceramic substrate comprises at least one diffusion barrier.

14. A housing for an implantable medical device, comprising:
a ceramic substrate;
a bonding structure formed on a periphery of the ceramic substrate; and
a biocompatible metal cap coupled to the ceramic substrate using the bonding structure to form a hermetically sealed enclosure, wherein at least one electronic element formed within the hermetically sealed enclosure is stably associated with the ceramic substrate.

15. The housing of claim 14, wherein the bonding structure is a metal ring formed on the periphery of the ceramic substrate, and wherein the biocompatible metal cap is welded to the metal ring formed on the periphery of the ceramic substrate.

16. The housing of claim 14, wherein the bonding structure is a metal film deposited on the periphery of the ceramic substrate using a cathodic arc deposition technique, and the biocompatible metal cap is welded to the metal film.

17. A method of forming a housing for an implantable medical device, comprising:
forming a ceramic substrate and a biocompatible metal cap;
stably associating at least one electronic element with the ceramic substrate;
forming a bonding structure on to the substrate;
coupling the biocompatible metal cap on the ceramic substrate using the bonding structure to form a hermetically sealed enclosure.

18. The method of claim 17, wherein the forming the bonding structure comprises forming a metal film on a periphery of the ceramic substrate using a cathodic arc deposition technique.

19. The method of claim 17, wherein the forming the bonding structure comprises forming a metal ring on a periphery of the ceramic substrate.

20. The method of claim 17, wherein the forming the ceramic structure comprises forming at least one diffusion barrier into the ceramic substrate.
